(19) United States
(12) Patent Application Publication
(10) Pub. No.: US 2006/0226453 A1
(43) Pub. Date: Oct. 12, 2006

(54) Methods of forming stress enhanced PMOS structures

(76) Inventors: Everett X. Wang, San Jose, CA (US); Martin D. Giles, Portland, OR (US); Philippe Matagne, Beaverton, OR (US); Roza Kotlyar, Portland, OR (US); Borna Obradovic, Hillsboro, OR (US); Mark Stettler, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/105,215

(22) Filed: Apr. 12, 2005

(51) Int. Cl. H01L 29/772; H01L 21/336

(52) U.S. Cl. 257/288; 438/585; 438/198; 438/300; 257/627

(57) ABSTRACT

Methods of forming a microelectronic structure are described. Embodiments of those methods include providing a gate structure disposed on a substrate comprising at least one recess, wherein a channel region is in a <110> direction, and then forming a compressive layer in the at least one recess.

### BACKGROUND OF THE INVENTION

Increased performance of microelectronic devices is usually a major factor considered during design, manufacture, and operation of those devices. For example, increasing movement of charged carriers in transistor channels, such as increasing the movement of positively charged holes in a P-type MOS device (PMOS) channel, may improve performance.

### BRIEF DESCRIPTION OF THE DRAWINGS

While the specification concludes with claims particularly pointing out and distinctly claiming certain embodiments of the present invention, the advantages of this invention can be more readily ascertained from the following description of the invention when read in conjunction with the accompanying drawings in which:

FIGS. 1a-1c represent methods of forming structures according to an embodiment of the present invention.

FIGS. 2a-2b represent methods of forming structures according to an embodiment of the present invention.

FIGS. 3a-3b represent structures of a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming and utilizing a microelectronic structure, such as a stress enhanced transistor structure, are described. Those methods may comprise providing a gate structure disposed on a substrate comprising at least one recess, and forming a compressive layer in the at least one recess, wherein the gate structure comprises a channel region in which holes flow from a source region to a drain region along a <110> direction.

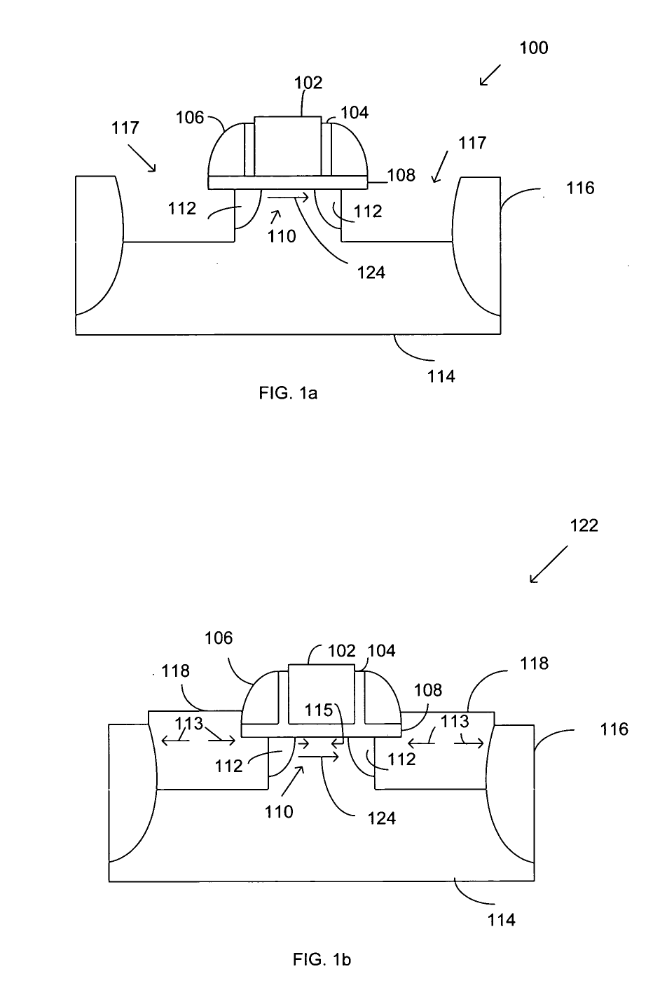

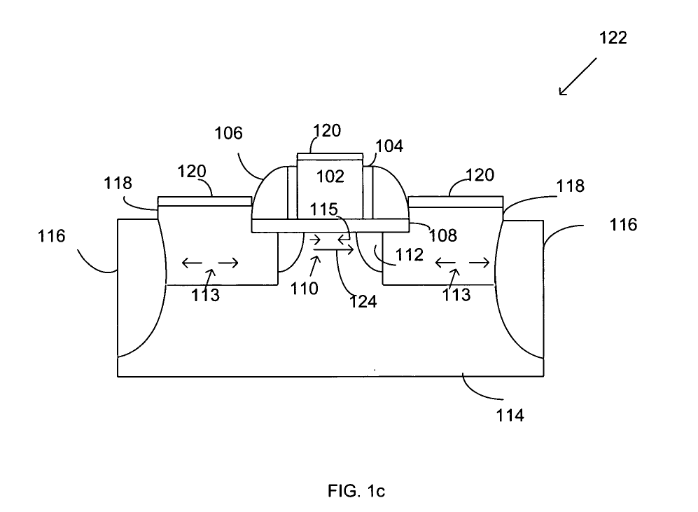

FIGS. 1a-1c illustrate an embodiment of a method of forming a microelectronic structure, such as a stress enhanced transistor structure, for example. FIG. 1a illustrates a gate structure 100 disposed on a substrate 114. The gate structure 100 may comprise a gate electrode 102. The gate electrode 102 may comprise any material suitable to fabricate a gate electrode, such as but not limited to polysilicon. In one embodiment, the gate electrode 102 may comprise a P type metal gate electrode, and may comprise materials, such as but not limited to nickel, ruthenium oxide, molybdenum nitride, tantalum nitride, molybdenum silicide, and tantalum silicide.

In one embodiment, the gate structure 100 may further comprise a gate dielectric layer 108, at least one inner spacer 104 and at least one outer spacer 106, and at least one tip region 112 as are known in the art. The substrate 114 may comprise a conducting plane and a surface, such as a top surface for example, that may be substantially oriented in the (110) crystallographic plane. In one embodiment, a channel region 110 may comprise the region between the at least one tip regions 112. In one embodiment, the channel region 110 may comprise a direction 124 from one tip region 112 to the other tip region 112 that is substantially the same as a <110> direction of the lattice structure of the substrate 114. In one embodiment, the gate structure 100 may comprise at least one isolation region 116. The gate structure 100 may comprise at least one recess 117. The at least one recess 117 may be formed in a prior processing step, and may be formed by etching the substrate 114, for example, as is well known in the art.

A stress inducing layer 118 may be formed within and/or on the at least one recess 117 to form a stress enhanced transistor structure 122 (FIG. 1b). In one embodiment, the stress inducing layer 118 may comprise a stress 113. In one embodiment, the stress 113 of the stress inducing layer 118 may induce a uniaxial compressive stress 115 in the channel region 110. In one embodiment, the uniaxial compressive stress 115 that may be induced in the channel region 110 may be in the same direction 124 as a <110> direction of the lattice structure of the substrate 114.

In one embodiment, the stress inducing layer 118 may comprise any such layer that when formed may apply and/or cause a uniaxial compressive stress 115 to be induced in the channel region 110. In one embodiment, the uniaxial compressive stress 115 may be in the <110> direction 124 of the channel region 110 of the stress enhanced transistor structure 122. In one embodiment, the stress inducing layer 118 may comprise silicon germanium, and in some embodiments may be formed by epitaxial growth, as is well known in the art. In one embodiment, the stress inducing layer 118 may comprise a silicon germanium layer comprising about 10 to about a 40 atomic percent germanium.

In one embodiment, the stress inducing layer 118 may comprise a source/drain region formed within the at least one recess 117. In one embodiment, the stress enhanced transistor structure 122 may comprise a planar device, such as a PMOS type planar transistor structure. In one embodiment, the stress inducing layer 118 may apply and/or induce a uniaxial compressive stress 115 in a <110> direction of the channel region 110 of above about 1 GPa. In one embodiment, holes may flow from the source region to the drain region along the <110> direction 124 of the channel region 110.

By inducing the uniaxial compressive stress 115 in the <110> direction 124 of the channel region 110 of the gate structure 100, positively charged holes may stay in their lowest transport effective mass in the <110> channel direction 124 where scattering suppression is also the strongest. Thus, significant hole mobility enhancement may occur when uniaxial compressive stress is applied in a <110> direction of a channel region of a device, such as the stressed enhanced transistor structure 122.

In one embodiment, the external resistance of a device fabricated according to the methods of the present invention, (such as a PMOS transistor, for example), may be reduced. In addition, because in some embodiments the stress inducing layer 118 may comprise a low resistance (for example, a heavily doped epitaxial source/drain region may comprise a low resistance) the external resistance of such a device may be significantly decreased, thus enabling enhanced performance.

In one embodiment, a silicide 120 may be formed on the stress inducing layer 118 (FIG. 1c). The silicide 120 may provide a means of electrically contacting the stress enhanced transistor structure 122 within a circuit and/or to other devices, for example. In one embodiment, the silicide 120 may comprise a nickel silicide, for example.

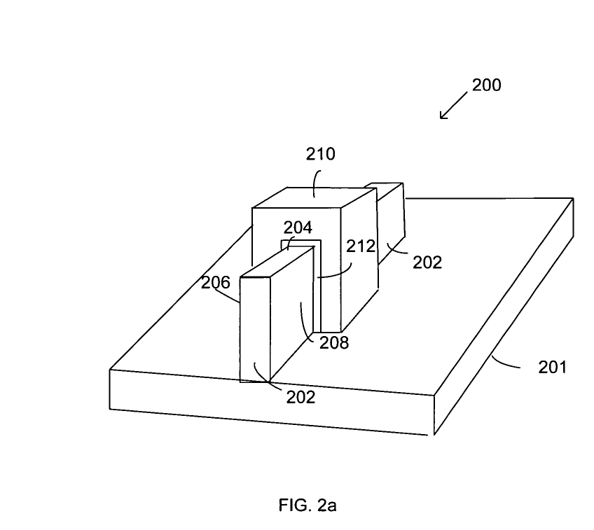

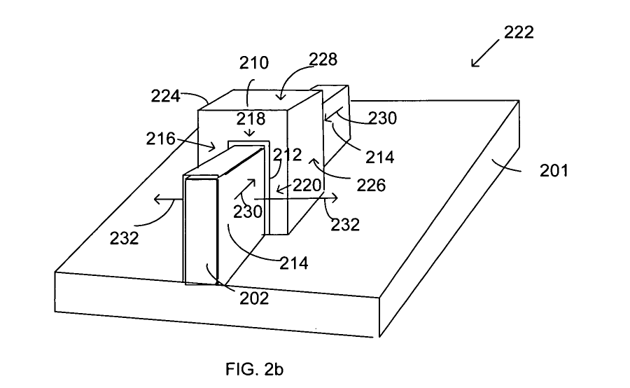

FIG. 2a depicts a gate structure 200 disposed on a substrate 201, according to another embodiment of the present invention. In one embodiment, the substrate 201 may comprise a conducting plane and at least one surface, such as a top surface and a lateral surface, for example, that may be substantially oriented in the (110) crystallographic plane. In one embodiment, the gate structure 200 may comprise a silicon body 202 comprising a top surface 204, a first sidewall 206 and a second sidewall 208, wherein the first and the second sidewalls 206, 208 of the silicon body 202 may be laterally opposite each other. In one embodiment, a gate electrode 210 may be disposed on the silicon body 202. In one embodiment, the gate electrode 210 may comprise polysilicon and/or a metal gate material.

In one embodiment, the gate electrode 210 may comprise an underlying gate dielectric layer 212, wherein the gate dielectric layer 212 may be disposed on at least one of the top surface 204 and the first and the second sidewalls 206, 208 of the silicon body 202. In one embodiment, a source and a drain region 214 may be formed on and/or in the silicon body 202, on opposite sides of the gate electrode 210 (FIG. 2b) to form a stress enhanced transistor structure 222. In one embodiment, the source and the drain region 214 may be formed on and/or in the silicon body 202 by forming a stress inducing layer, such as but not limited to an epitaxial silicon germanium layer on the silicon body 202.

In one embodiment, the stress enhanced transistor structure 222 may comprise a trigate transistor structure, wherein the stress enhanced transistor structure 222 may comprise three gates (a first and second lateral gate 216, 220 and a top gate 218) and three channels. The portion of the semiconductor body 202 located between the source and drain region 214 may define a channel region of the stress enhanced transistor structure 222. In one embodiment, a first lateral channel 224 may extend between the source and drain regions 214 on the first sidewall 206 of the silicon body 202, a second lateral channel 226 may extend between the source and drain regions 214 on the second sidewall 208 of the silicon body 202, and a top channel 228 may extend between the source and drain regions 214 on the top surface 204 of silicon body 202.

In one embodiment, the first and second lateral channels 224, 226 may comprise a <110> direction and/or (110) plane. In one embodiment, the first and second lateral channels 224, 226 may comprise a direction and/or plane extending from the source region to the drain region 214 that is substantially the same as a <110> direction and/or (110) plane of the lattice structure of the silicon body 202 and/or substrate 201.

In another embodiment, the stress enhanced transistor structure 222 may comprise a double gate structure, wherein the stress enhanced transistor structure 222 comprises two gates and two channels. For example, the stress enhanced transistor structure 222 may not comprise a top gate channel, but may comprise a first and a second lateral channel. In one embodiment, the first and second lateral channels may comprise a <110 direction> and/or a (110) plane.

In one embodiment, the source and the drain regions 214 that comprise the stress inducing layer may apply a uniaxial compressive stress 230 in a direction of at least one channel of the stress enhanced transistor structure 222, wherein the at least one channel comprises a <110> direction and/or a (110) plane. In another embodiment, the source and the drain regions 214 may apply a uniaxial tensile stress 232 perpendicular to at least one channel of the stress enhanced transistor structure 222, wherein the at least one channel comprises a <110> direction and/or a (110) plane.

By inducing the uniaxial compressive stress 230 and/or the uniaxial tensile stress 232 in the at least one <110> channel direction and/or (110) plane, positively charged holes may stay in their lowest transport effective mass in the <110> channel direction and/or (110) channel plane where scattering suppression is also the strongest. Thus, significant hole mobility enhancement may occur when uniaxial compressive stress 230 is applied along the <110> channel direction and/or (110) plane and/or when uniaxial tensile stress 232 is applied perpendicular to a <110> channel direction and/or (110) plane of at least one channel of the stressed enhanced transistor structure 222.

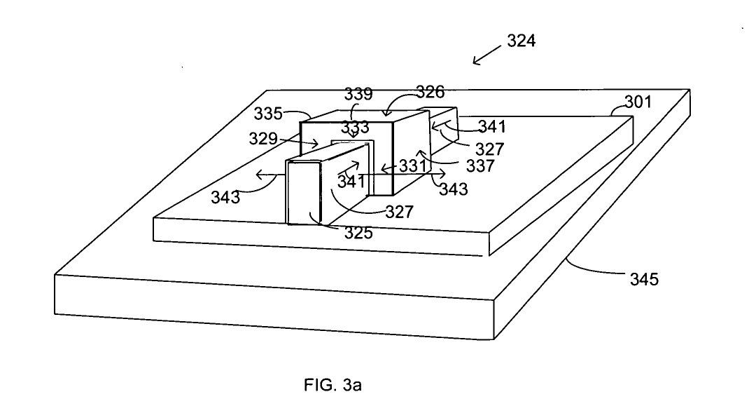

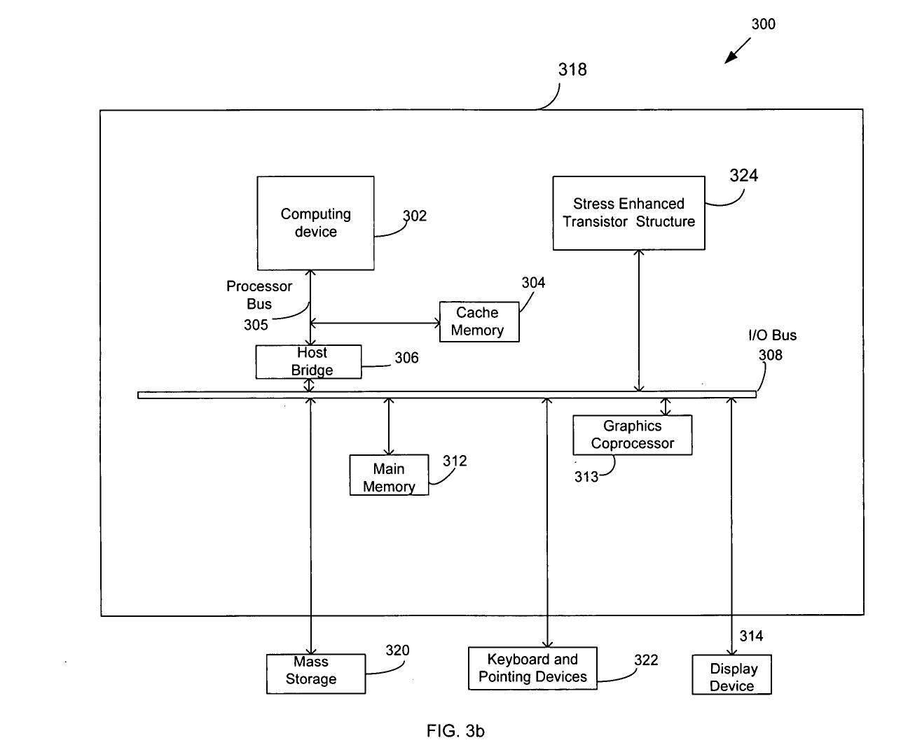

FIG. 3a depicts a stress enhanced transistor structure 324 disposed on a substrate 301, similar to the stress enhanced transistor structure 222 of FIG. 2b, for example. In one embodiment, the stress enhanced transistor structure 324 may comprise a gate electrode 326 disposed on a silicon body 325, and a source and a drain region 327 disposed on and/or in the silicon body 325. In one embodiment, the stress enhanced transistor structure 324 may comprise a tri-gate transistor structure, wherein the stress enhanced transistor structure 324 may comprises three gates (a first and second lateral gate 329, 331 and a top gate 333) and three channels (a first lateral channel 335, a second lateral channel 337 and a top channel 339.

In one embodiment, the first and second lateral channels 335, 337 may comprise a <110> direction and/or a (110) plane. In one embodiment, the first and second lateral channels 335, 337 may comprise a direction and/or plane extending from the source region to the drain region 214 that is substantially the same as a <110> direction and/or (110) plane of the lattice structure of the silicon body 202 and/or substrate 201.

In one embodiment, the source and the drain regions 327 may apply a uniaxial compressive stress 341 in a direction of at least one channel of the stress enhanced transistor structure 324, wherein the at least one channel comprises a <110> direction and/or (110) plane. In another embodiment, the source and the drain regions 327 may apply a uniaxial tensile stress 343 perpendicular to at least one channel of the stress enhanced transistor structure 324, wherein the at least one channel comprises a <110> direction and/or (110) plane.

In one embodiment, the stress enhanced transistor structure 324 may be disposed on a package substrate 345, that in one embodiment may comprise a layer of a package structure. The substrate 345 may comprise a package structure (not shown), such as a ball grid array package, for example, that may be coupled with a motherboard, such as a printed circuit board (PCB) (not shown) for example.

FIG. 3b is a diagram illustrating an exemplary system 300 that is capable of being operated with methods for fabricating a microelectronic structure, such as the stress enhanced transistor structure 324 of FIG. 3a, for example. It will be understood that the present embodiment is but one of many possible systems in which the stress enhanced transistor structures of the present invention may be used.

In the system 300, the stress enhanced transistor structure 324 may be communicatively coupled to a printed circuit board (PCB) 318 by way of an I/O bus 308. The communicative coupling of the stress enhanced transistor structure 324 may be established by physical means, such as through the use of a package and/or a socket connection to mount the stress enhanced transistor structure 324 to the PCB 318 (for example by the use of a chip package, interposer and/or a land grid array socket). The stress enhanced transistor structure 324 may also be communicatively coupled to the PCB 318 through various wireless means (for example, without the use of a physical connection to the PCB), as are well known in the art.

The system 300 may include a computing device 302, such as a processor, and a cache memory 304 communicatively coupled to each other through a processor bus 305. The processor bus 305 and the I/O bus 308 may be bridged by a host bridge 306. Communicatively coupled to the I/O bus 308 and also to the stress enhanced transistor structure 324 may be a main memory 312. Examples of the main memory 312 may include, but are not limited to, static random access memory (SRAM) and/or dynamic random access memory (DRAM), and/or some other state preserving mediums. The system 300 may also include a graphics coprocessor 313, however incorporation of the graphics coprocessor 313 into the system 300 is not necessary to the operation of the system 300. Coupled to the I/O bus 308 may also, for example, be a display device 314, a mass storage device 320, and keyboard and pointing devices 322.

These elements perform their conventional functions well known in the art. In particular, mass storage 320 may be used to provide long-term storage for the executable instructions for a method for forming stress enhanced transistor structures in accordance with embodiments of the present invention, whereas main memory 312 may be used to store on a shorter term basis the executable instructions of a method for a forming stress enhanced transistor structures in accordance with embodiments of the present invention during execution by computing device 302. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 312 may supply the computing device 302 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures, such as integrated circuits, are well known in the art. Therefore, the Figures provided herein illustrate only portions of an exemplary microelectronic structure that pertains to the practice of the present invention. Thus the present invention is not limited to the structures described herein.

What is claimed is:

1. A method comprising:
providing a gate structure disposed on a substrate comprising at least one recess, wherein the gate structure comprises a channel region in a <110> direction; and
forming a stress inducing layer in the at least one recess.

2. The method of claim 1 wherein forming the stress inducing layer comprises forming a silicon germanium layer.

3. The method of claim 2 wherein forming a silicon germanium layer comprises forming a silicon germanium layer by epitaxial growth.

4. The method of claim 1 wherein forming the stress inducing layer comprises forming a layer that applies a uniaxial compressive stress in the direction of the channel region.

5. The method of claim 4 wherein forming a layer that applies a uniaxial compressive stress in the direction of the channel region comprises forming a source/drain region that applies a uniaxial compressive stress in the direction of the channel region, wherein the channel region comprises silicon.

6. The method of claim 1 wherein forming a stress inducing layer comprises forming a source/drain region that applies a uniaxial compressive stress above about 1 GPa.

7. The method of claim 1 further comprising forming a silicide on the stress inducing layer.

8. The method of claim 1 wherein the substrate surface comprises a 110 orientation.

9. A structure comprising:
a gate structure disposed on a substrate; and
a uniaxial compressive stress in a direction of a channel region of the gate structure, wherein the channel region comprises a <110> direction.

10. The structure of claim 9 wherein the substrate surface comprises a (110) orientation.

11. The structure of claim 9 wherein the channel region comprises silicon.

12. The structure of claim 9 wherein the uniaxial compressive stress comprises a magnitude of at least about 1 GPa.

13. The structure of claim 9 further comprising a source/drain adjacent to the gate structure, wherein the source/drain comprises a layer that is capable of applying a uniaxial compressive stress to the channel region.

14. The structure of claim 13 wherein the source/drain comprises an epitaxial silicon germanium layer.

15. A structure comprising:
a gate structure, wherein the gate structure comprises a silicon body comprising a top surface and first and second laterally opposite sidewalls, and a gate electrode disposed on the silicon body; and
a uniaxial compressive stress in a direction of at least one channel, wherein at least one of the at least one channels comprises a <110> direction.

16. The structure of claim 15 further comprising a source and drain region in the silicon body on opposite sides of the gate electrode, wherein the source and drain region comprises a layer that is capable of applying a uniaxial compressive stress to the channel.

17. The method of claim 16 wherein the source and drain region comprises a silicon germanium layer.

18. The structure of claim 15 wherein the gate electrode comprises an underlying gate dielectric layer, wherein the gate dielectric layer is disposed on at least one of the top surface and the first and second laterally opposite sidewalls of the silicon body.

19. The structure of claim 15 wherein the gate structure comprises a first and a second lateral channel, wherein the first and the second lateral channel comprise a <110> direction.

20. The structure of claim 19 further comprising wherein the gate structure comprises a top surface channel.

21. The structure of claim 15 further comprising a uniaxial tensile stress perpendicular to at least one channel of the gate structure.

22. A system comprising:
a device comprising a gate structure disposed on a substrate, wherein at least one channel of the gate structure comprises a <110> direction, and wherein at least one of the at least one channel comprises a uniaxial compressive stress in the <110> direction;
a bus communicatively coupled to the device; and
a DRAM communicatively coupled to the bus.

23. The system of claim 22 wherein the gate structure comprises a silicon body comprising a top surface and first and second laterally opposite sidewalls, and a gate electrode disposed on the silicon body.

24. The system of claim 22 further comprising a source and drain region on opposite sides of the gate electrode, wherein the source and drain region comprises a material that is capable of applying a uniaxial compressive stress in the direction of the at least one channel.

25. The system of claim 24 wherein the source and drain region comprises a material that is capable of applying a uniaxial tensile stress perpendicular to the at least one channel.

26. The system of claim 22 wherein the gate structure comprises at least one of a first and a second lateral channel and a top surface channel.

27. The system of claim 22 wherein the device comprises a planar transistor, wherein a source/drain adjacent to the gate structure is capable of applying a uniaxial compressive stress to the channel.

28. The system of claim 27 wherein the source and drain region comprises silicon germanium.
